(19) United States
(12) Patent Application Publication
(10) Pub. No.: US 2011/0232729 A1
(43) Pub. Date: Sep. 29, 2011

(54) SOLAR BATTERY ELEMENT AND METHOD FOR PRODUCING THE SOLAR BATTERY ELEMENT

(75) Inventors: Yoichi HOSOYA, Ashigarakami-gun (JP); Hideharu NAGASAWA, Ashigarakami-gun (JP); Koukichi WAKI, Ashigarakami-gun (JP); Masashi SHIRATA, Ashigarakami-gun (JP)

(73) Assignee: FUJIFILM CORPORATION, Tokyo (JP)

(21) Appl. No.: 13/073,204

(22) Filed: Mar. 28, 2011

(30) Foreign Application Priority Data
Mar. 29, 2010 (JP) 2010-074931

(51) Int. Cl. H01L 31/0352; H01L 31/18

(52) U.S. Cl. 136/252; 438/63; 257/E31.032

(57) ABSTRACT

A solar battery element has a structure equipped with: photoelectric converting semiconductor particles formed by a particulate base substance, semiconductor layers of a first conductive type formed by a material different from that of the particulate base substance that cover at least portions of the particulate base substance, and semiconductor layers of a second conductive type that cover portions of the semiconductor layers of the first conductive type so as to form pn junctions therewith; a first electrode that contacts the semiconductor layers of the first conductive type; a second electrode that contacts the semiconductor layers of the second conductive type; and an insulating binder for immobilizing the photoelectric converting semiconductor particles between the first electrode and the second electrode.

### BACKGROUND OF THE INVENTION

1. Field of the Invention

The present invention is related to a solar battery element equipped with photoelectric converting semiconductor particles and a method for producing the solar battery element. Particularly, the present invention is related to an element structure and a method of production that realize decreased production costs.

2. Description of the Related Art

Photoelectric converting elements having layered structures, constituted by a lower electrode (underside electrode), a photoelectric converting semiconductor layer that generates electric charges by absorbing light, and an upper electrode, are utilized as solar batteries and the like.

Conventional mainstream solar batteries are Si series solar batteries that employ bulk monocrystalline Si, bulk polycrystalline Si, or thin film amorphous Si. Currently, research and development is being performed with respect to solar batteries that employ semiconductor compounds that do not depend on Si. Known semiconductor compound solar batteries include: bulk type solar batteries that employ GaAs, etc. and thin film type solar batteries, such as CIS (Cu—In—Se) type solar batteries and CIGS (Cu—In—Ga—Se) type solar batteries formed by IB group elements, IIIB group elements, and VIB group elements. It is reported that the CIS type and the CIGS type have high light absorption rates and exhibit high energy converting efficiency.

Meanwhile, solar batteries, in which a great number of spherical semiconductors (semiconductor particles) are two dimensionally arranged as a single layer film, have been proposed in Japanese Unexamined Patent Publication No. 2001-267609 and U.S. Patent Application Publication No. 20070089782.

Japanese Unexamined Patent Publication No. 2001-267609 discloses a method for producing a solar battery. In this method, spherical particles constituted by semiconductor core portions of a first conductive type (p type silicon spheres) and semiconductor surface coatings of a second conductive type (n type silicon layers) are fitted into the mesh of a conductive mesh member to arrange and immobilize the spherical particles two dimensionally. Next, portions of the spherical particles are ground to expose the semiconductor core portions of the first conductive type. Thereafter, the conductive mesh member is caused to penetrate through an insulting member such that the insulating member contacts the exposed semiconductor core portions of the first conductive type.

U.S. Patent Application Publication No. 20070089782 discloses a solar battery that employs core shell type particles. The core shell type particles are formed by glass cores being coated with back contact layers, then CIS semiconductor layers being provided to cover the back contact layers. The solar battery of U.S. Patent Application Publication No. 20070089782 is produced by embedding the core shell type particles in an insulating support layer such that portions thereof are exposed at a first surface of the support layer. Then, portions of the support layer and portions of the core shell type particles are removed at a second surface of the support layer, such that the back contact layers of the core shell type particles are exposed. Thereafter, a back contact layer is formed on the second surface of the insulating support layer, and a front contact layer is formed on the first surface of the insulating support layer.

The method for producing the solar battery of Japanese Unexamined Patent Publication No. 2001-267609 requires complex processing steps, such as the step of forming apertures in the insulating member for the conductive member to penetrate through without causing shorts. In addition, highly accurate positioning is required between the conductive member that penetrates through the insulating member and the spherical particles. Further, in order to produce a favorable solar battery by performing the complex processing steps and the processing steps that require high degrees of accuracy, it is necessary for the shapes of each spherical particle to have an extremely high sphericity.

Meanwhile, the method for producing the solar battery disclosed in U.S. Patent Application Publication No. 20070089782 removes portions of the core shell type particles, and forms the back contact layer on the exposed surfaces to connect with the back contact layers within the core shell type particles. At this time, in the case that the core shell type particles are of a two layer structure such that they have p-n junctions, portions of p type semiconductor layers and portions of n type semiconductor layers will contact the back contact layer simultaneously. Photoelectric converting efficiency will deteriorate greatly by both types of semiconductor layers contacting a single electrode.

### SUMMARY OF THE INVENTION

The present invention has been developed in view of the foregoing circumstances. It is an object of the present invention to provide a solar battery element that enables high photoelectric converting efficiency and is equipped with photoelectric converting semiconductor particles of a structure that can be produced by simple steps and at low cost. It is another object of the present invention to provide a method for producing the solar battery element.

A first solar battery element of the present invention is characterized by comprising:

photoelectric converting semiconductor particles formed by a particulate base substance, semiconductor layers of a first conductive type formed by a material different from that of the particulate base substance that cover at least portions of the particulate base substance, and semiconductor layers of a second conductive type that cover portions of the semiconductor layers of the first conductive type so as to form pn junctions therewith;

a first electrode that contacts the semiconductor layers of the first conductive type;

a second electrode that contacts the semiconductor layers of the second conductive type; and

an insulating binder for immobilizing the photoelectric converting semiconductor particles between the first electrode and the second electrode.

The first conductive type and the second conductive type are different from each other. In the case that the first conductive type is the p type, the second conductive type is the n type, and in the case that the first conductive type is the n type, the second conductive type is the p type.

Here, the semiconductor layers of the second conductive type may be semiconductor layers that form p-n junctions at least at the interfaces with the semiconductor layers of the first conductive type when ultimately combined therewith to construct a solar battery. Accordingly, the semiconductor layers of the second conductive type may be formed as layers having a conductive type different from that of the semiconductors of the first conductive type in advance, or may be semiconductor layers of either conductive type when formed, to which heat is applied during a later production step to generate layers of the second conductive type at the interface with the semiconductor layers of the first conductive type.

It is preferable for the semiconductor layers of the first conductive type to cover the entire surface of the particulate base substance in the photoelectric converting semiconductor particles.

It is preferable for the particle size of the particulate base substance to be within a range from 5 μm to 1000 μm; and for the ratio of the particle size of the particulate base substance with respect to an average total thickness of the semiconductor layers of the first conductive type and the semiconductor layers of the second conductive type to be within a range from 2 to 1000. The particle size of the particulate base substance is defined as the maximum dimension thereof. It is preferable for the particulate base substance to be spherical. In the case that the particulate base substance is spherical, the particle size refers to the diameter thereof.

It is preferable for the semiconductor layers of the first conductive type to be p type group IB-IIIB-VIB semiconductors or p type group IB-IIB-IVB-VIB semiconductors.

It is preferable for the semiconductor layers of the second conductive type to be one of n type IIB-VIB group semiconductors, n type IB-IIB-IIIB-VIB group semiconductors, and n type IB-IIIB-IVB-VIB group semiconductors.

A second solar battery element of the present invention is characterized by comprising:

photoelectric converting semiconductor particles formed by a conductive particulate base substance, semiconductor layers of a first conductive type that cover the particulate base substance such that at least portions thereof are exposed, and semiconductor layers of a second conductive type that cover at least portions of the semiconductor layers of the first conductive type so as to form pn junctions therewith;

a first electrode that contacts the particulate base substance;

a second electrode that contacts the semiconductor layers of the second conductive type; and

an insulating binder for immobilizing the photoelectric converting semiconductor particles between the first electrode and the second electrode.

In the second solar battery element of the present invention, it is desirable for the particle size of the conductive particulate base substance to be within a range from 5 μm to 1000 μm; and for the ratio of the particle size of the particulate base substance with respect to an average total thickness of the semiconductor layers of the first conductive type and the semiconductor layers of the second conductive type to be within a range from 2 to 1000. The particle size of the conductive particulate base substance is defined as the maximum dimension thereof. It is preferable for the conductive particulate base substance to be spherical. In the case that the conductive particulate base substance is spherical, the particle size refers to the diameter thereof.

In the second solar battery element of the present invention, it is desirable for the semiconductor layers of the first conductive type to be p type group IB-IIIB-VIB semiconductors or p type group IB-IIB-IVB-VIB semiconductors.

In the second solar battery element of the present invention, it is desirable for the semiconductor layers of the second conductive type to be one of n type IIB-VIB group semiconductors, n type IB-IIB-IIIB-VIB group semiconductors, and n type IB-IIIB-IVB-VIB group semiconductors.

A first method for producing a solar battery element of the present invention is characterized by comprising the steps of:

producing first semiconductor particles, by coating a particulate base substance with semiconductor layers of a first conductive type formed by a material different from that of the particulate base substance such that at least portions of the particulate base substance are covered;

arranging the first semiconductor particles in a plate shaped insulating binder such that the portions covered by the semiconductor layers of the first conductive type are exposed at both a first surface and a second surface of the insulating binder;

forming a first electrode on the first surface of the insulating binder so as to contact the semiconductor layers of the first conductive type;

forming semiconductor layers of a second conductive type on the semiconductor layers of the first conductive type, which are exposed at the second surface of the insulating binder; and

forming a second electrode on the semiconductor layers of the second conductive type.

A second method for producing a solar battery element of the present invention is characterized by comprising the steps of:

producing first semiconductor particles, by coating a conductive particulate base substance with semiconductor layers of a first conductive type;

arranging the first semiconductor particles in a plate shaped insulating binder such that the portions covered by the semiconductor layers of the first conductive type are exposed at both a first surface and a second surface of the insulating binder;

grinding the semiconductor layers of the first conductive type which are exposed at the first surface of the insulating binder to expose the conductive particulate base substance;

forming a first electrode so as to contact the exposed conductive particulate base substance;

forming semiconductor layers of a second conductive type on the semiconductor layers of the first conductive type, which are exposed at the second surface of the insulating binder; and

forming a second electrode on the semiconductor layers of the second conductive type.

The first solar battery element of the present invention is equipped with the photoelectric converting semiconductor particles formed by the particulate base substance of a material different from the semiconductor layers of the first conductive type. Therefore, a material less expensive than a photoelectric converting semiconductor material which is employed as the semiconductor layer of the first conductive type can be used as the base substance. Accordingly, production costs can be decreased.

The second solar battery element of the present invention is equipped with the photoelectric converting semiconductor particles formed by the conductive particulate base substance. The particulate base substance is in contact with the first electrode, and also in contact with the entire surface of the semiconductor layer of the first conductive type. Therefore, the efficiency of drawing out electric charges from the photoelectric converting semiconductor particles is improved, and high photoelectric converting efficiency is obtained as a result. In addition, a material less expensive than a photoelectric converting semiconductor material which is employed as the semiconductor layer of the first conductive type can be used as the base substance. Accordingly, production costs can be decreased.

The solar battery disclosed in U.S. Patent Application Publication No. 20070089782 is produced by a method including the steps of removing portions of the core shell type particles, and forming the back contact layer to connect with the back contact layers within the particles on the exposed surfaces. Therefore, portions of p type semiconductor layers and portions of n type semiconductor layers will contact the back contact layer simultaneously and cause short circuits in the case that the core shell type particles are of a two layer structure such that they have p-n junctions, resulting in a great deterioration in photoelectric converting efficiency. In contrast, the first and second solar battery elements of the present invention are of structures in which the semiconductor layers of the second conductive type do not contact the first electrode. Therefore, improvements in photoelectric converting efficiency can be obtained compared to the solar battery disclosed in U.S. Patent Application Publication No. 20070089782.

The solar battery disclosed in Japanese Unexamined Patent Publication No. 2001-267609 requires complex processing steps, such as the steps of forming apertures in the insulating member, and for causing the conductive member to penetrate therethrough. In contrast, the first and second solar battery elements of the present invention can be produced without complex processing steps, and therefore productivity is improved. As a result, solar batteries can be provided at lower costs.

According to the first method for producing a solar battery of the present invention, the first solar battery element of the present invention can be produced without complex processing steps, and high productivity can be obtained.

According to the second method for producing a solar battery of the present invention, the second solar battery element of the present invention can be produced without complex processing steps, and high productivity can be obtained.

### BRIEF DESCRIPTION OF THE DRAWINGS

FIG. 1 is a sectional diagram that schematically illustrates the structure of a solar battery element according to a first embodiment of the present invention.

FIG. 2 is a collection of sectional diagrams that schematically illustrate the steps for producing the solar battery element of the first embodiment.

FIG. 3 is a sectional diagram that illustrates a portion of a solar battery 3, in which a plurality of solar battery elements 1 are arranged.

FIG. 4 is a sectional diagram that schematically illustrates the construction of a solar battery element according to a second embodiment of the present invention.

FIG. 5 is a sectional diagram that illustrates a portion of a solar battery 4, in which a plurality of solar battery elements 2 are arranged.

### DESCRIPTION OF THE PREFERRED EMBODIMENTS

Hereinafter, solar batteries of the present invention will be described with reference to the attached drawings. Note that the dimensions of components in the drawings are different from the actual dimensions thereof, to facilitate visual recognition.

### <First Embodiment of Solar Battery Element>

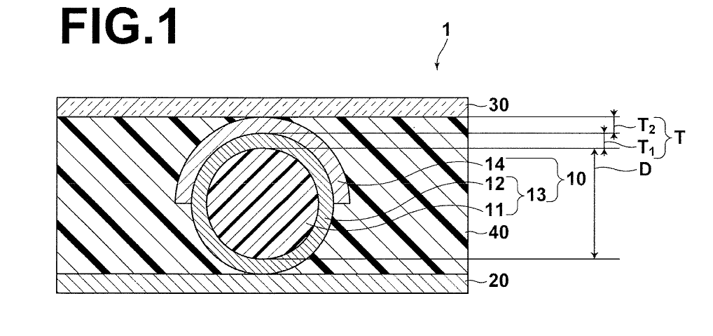

FIG. 1 is a sectional diagram that schematically illustrates the structure of a solar battery element 1 according to a first embodiment of the present invention.

As illustrated in FIG. 1, the solar battery element 1 of the first embodiment is constituted by: a photoelectric converting semiconductor particle 10 formed by a particulate base substance 11, a semiconductor layer 12 of a first conductive type formed by a material different from that of the particulate base substance 11 that covers at least a portion of the particulate base substance 11, and a semiconductor layer 14 of a second conductive type that covers a portion of the semiconductor layer 12 of the first conductive type; a first electrode 20 that contacts the semiconductor layer 12 of the first conductive type; a second electrode 30 that contacts the semiconductor layer 14 of the second conductive type; and an insulating binder 40 for immobilizing the photoelectric converting semiconductor particle 10 between the first electrode 20 and the second electrode 30.

### (Electrodes)

The first electrode 20 and the second electrode 30 are formed by conductive materials. In the present embodiment, it is necessary for the second electrode 30, which functions as a light incident surface, to be transparent. Alternatively, the first electrode 20 may be formed by a transparent material, and the first electrode 20 may function as a light incident surface.

The main component of the first electrode 20 is not particularly limited, but it is preferable for the main component to be a metal, from the viewpoint of favorable conductivity. Preferred metals include: Mo; Cr; W; and combinations thereof. Mo is particularly preferred. The thickness of the first electrode 20 is not particularly limited, and a thickness within a range from 0.3 μm to 1.0 μm is preferred.

The main component of the second electrode 20 is not particularly limited. Preferred materials include: ZnO; ITO (Indium Tin Oxide); SnO₂; and combinations thereof. These materials are preferred because they are highly transmissive with respect to light, and have low resistance. The second electrodes 30 are formed by doping these materials to yield a desired conductive type. Examples of dopants include elements such as Ga, Al, and B.

The thickness of the second electrode 30 is not particularly limited, and a thickness within a range from 0.6 μm to 1.0 μm is preferred.

The first electrode 20 and the second electrode 30 may be single layered structures or layered structures, such as two layered structures. Particularly, it is preferable for the second electrode 30 that contacts the semiconductor layer 14 of the second conductive type to be of a two layered structure having an i layer having an i conductive type at the side of the semiconductor layer 14 of the second conductive type, and a layer of the second conductive type.

The film forming method by which the first electrode 20 and the second electrode 30 are formed is not particularly limited. Vapor phase film forming methods, such as the electron beam vapor deposition method and the sputtering method are examples of film forming methods by which the first electrode 20 and the second electrode 30 may be formed.

### (Photoelectric Converting Semiconductor Particle)

The shape of the photoelectric converting semiconductor particle 10 may be any one of a sphere, an oval sphere, a cylinder, and a polygonal column. However, it is particularly preferable for the photoelectric converting semiconductor particle 10 to be spherical.

As described previously, the photoelectric converting semiconductor particle 10 is formed by the particulate base substance 11, the semiconductor layer 12 of a first conductive type that covers at least a portion of the particulate base substance 11, and the semiconductor layer 14 of a second conductive type that covers a portion of the semiconductor layer 12 of the first conductive type. It is preferable for the semiconductor layer 12 of the first conductive type to cover the entire surface of the particulate base substance 11, as in the photoelectric converting semiconductor particle 10 of the present embodiment illustrated in FIG. 1. In addition, in the present embodiment, the semiconductor layer 14 of the second conductive type is provided only on the upper portion of a first semiconductor particle 13 constituted by the particulate base substance 11 and the semiconductor layer 12 that covers the entire surface of the particulate base substance 11. That is, a configuration is adopted such that the semiconductor layer 14 does not contact the second electrode 30.

It is preferable for the particle size of the particulate base substance 11 to be within a range from 5 μm to 1000 μm. It is preferable for the ratio of the particle size of the particulate base substance 11 with respect to an average total thickness of the semiconductor layer 12 of the first conductive type and the semiconductor layer 14 of the second conductive type to be within a range from 2 to 1000. The particle size of the particulate base substance 11 is defined as the diameter D of the particulate base substance 11 in the case that the particulate base substance 11 is spherical, and the maximum dimension thereof in the case that the particulate base substance 11 is of a different shape. The thickness T₁ of the semiconductor layer 12 of the first conductive type and the thickness T₂ of the semiconductor layer 14 of the second conductive type are defined as the average thickness of the semiconductor layers 12 and 14 at the regions where they are laminated. The average total thickness T of the semiconductor layers 12 and 14 is expressed as T=T₁+T₂.

The particle size of the particulate base substance 11 may be measured by the laser scattering method, as performed by the laser diffraction/scattering particle size distribution measuring apparatus LA-920 by Horiba, for example. In addition, the thickness of each semiconductor laser may be measured by embedding a particle, on which the semiconductor layers have been formed, in resin, then cutting out a cross section of the particle by microtomy, ion milling, FIB or the like, then observing the cross section with a TEM. The average thickness of each layer is an average of measured thicknesses at a plurality of locations within regions at which the semiconductor layers 12 and 14 are layered.

The material of the particulate base substance is not particularly limited, as long as it is different from the material of the semiconductor layer of the first conductive type, and may be an insulating material, a semiconductor material, or a conductive material. It is particularly preferable for a material which is less expensive than the photoelectric converting semiconductor material to be employed, from the viewpoint of reducing costs. Specific preferred materials are those that can be produced into spheres with little variation in particle size, such as glass, zirconia, and titanium oxide.

The material of the semiconductor layer of the first conductive type is not particularly limited, as long as it is a semiconductor material that has photoelectric converting properties that generate electric charges by absorbing light. From the viewpoints of light absorbing efficiency and manufacturing costs, p type group IB-IIIB-VIB semiconductors are particularly preferred. More specifically, a group IB-IIIB-VIB semiconductor constituted by: a group IB element that includes copper and/or silver; a group IIIB element that includes at least one of aluminum, indium, and gallium; and a group VIB element that includes at least one of sulfur, selenium, and tellurium is preferred.

Note that the descriptions of the groups of elements are based on the short format periodic table. In the present specification, semiconductor compounds constituted by group IB elements, group IIIB elements, and group VIB elements may also be expressed as “group I-III-VI semiconductors”. The group I-III-VI semiconductors may be constituted by a single or a plurality of group IB elements, a single or a plurality of group IIIB elements, and a single or a plurality of group VIB elements.

Specific examples of group I-III-VI semiconductors include: CuAlS₂; CuGaS₂; CuInS₂; CuAlSe₂; CuGaSe₂; CuInSe₂ (CIS); AgAlS₂; AgGaS₂; AgInS₂; AgAlSe₂; AgGaSe₂; AgInSe₂; AgAlTe₂; AgGaTe₂; AgInTe₂; Cu(In₁₋ₓGaₓ) Se₂ (CIGS); Cu(In₁₋ₓAlₓ) Se₂; Cu(In₁₋ₓGaₓ)(S, Se)₂; Ag(In₁₋ₓAlₓ)Se₂; and Ag(In₁₋ₓGaₓ)(S, Se)₂.

From among these, CuInS₂, CuInSe₂, Cu(In, Ga)S₂, Cu(In, Ga)Se₂, or selenium sulfides of these materials are particularly preferred. Chalcopyrite structures are preferred, but other structures may be adopted.

In addition, the semiconductor layer of the first conductive type may be constituted by one or a plurality of types of semiconductor materials other than group I-III-VI semiconductors. Examples of semiconductor materials other than group I-III-VI semiconductors include: semiconductors constituted by group IVB elements such as Si (group IV semiconductors); Cu₂ZnSnS₄ (CZTS: group I-II-IV-VI semiconductors); semiconductors constituted by group IIIB elements and group VB elements such as GaAs (group III-V semiconductors); and semiconductors constituted by group IIB elements and group VIB elements such as CdTe (group II-VI semiconductors).

Meanwhile, the semiconductor material of the semiconductor layer 14 of the second conductive type is not particularly limited, as long as a p-n junction can be formed when combined with the semiconductor layer 12 of the first conductive type.

It is preferable for the semiconductor layer of the second conductive type to be constituted by one of n type IIB-VIB group semiconductors, n type IB-IIB-IIIB-VIB group semiconductors, and n type IB-IIIB-IVB-VIB group semiconductors. Examples of such semiconductors include: CdS; ZnS; ZnO; ZnMgO; and ZnS(O, OH). Further, any one of n type IIB-VIB group semiconductors, n type IB-IIB-IIIB-VIB group semiconductors, and n type IB-IIIB-IVB-VIB group semiconductors may be employed.

It is preferable for the thickness T₂ of the semiconductor layer 14 of the second conductive type to be within a range from 0.03 μm to 0.1 μm. The semiconductor layer 14 of the second conductive type may be formed so as to cover the semiconductor layer 12 of the first conductive type excluding the portion thereof in contact with the first electrode 20.

The photoelectric converting semiconductor particle 10 may include other arbitrary components in addition to semiconductors and impurities for obtaining desired conductive types, as long as they do not adversely influence the properties thereof.

### (Insulating Binder)

The material of the insulating binder 40 is not particularly limited, as long as it is an insulating material that can immobilize the photoelectric converting semiconductor particle 10 between the first and second electrodes 20 and 30. Specific preferred examples include resins, such as epoxy resins, polyethylene resins, and polyurethane resins, and mixtures thereof. The layer thickness of the insulating binder 40 is not particularly limited, as long as it is a sufficient to enable the semiconductor layer 12 of the first conductive type to contact the first electrode 20 and the semiconductor layer 14 of the second conductive type to contact the second electrode 30, and capable of stably immobilizing the photoelectric converting semiconductor particle 10.

### (Other Structures)

A great number of the solar battery elements 1 having the configuration described above are arranged two dimensionally and packaged by being laminated using an inexpensive material such as PET to insulate them from the exterior, to form a solar battery module.

In addition, various protective layers, filter layers, light scattering reflecting layers and the like may be added to the element structure of the present invention as necessary.

### <Method for Producing the Solar Battery Element of the First Embodiment>

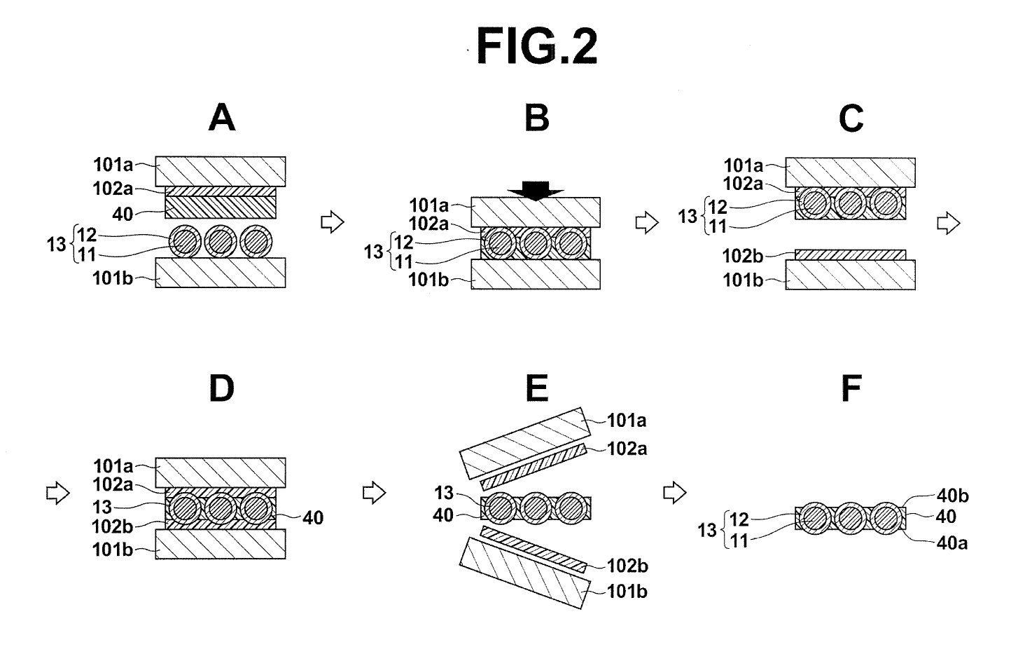

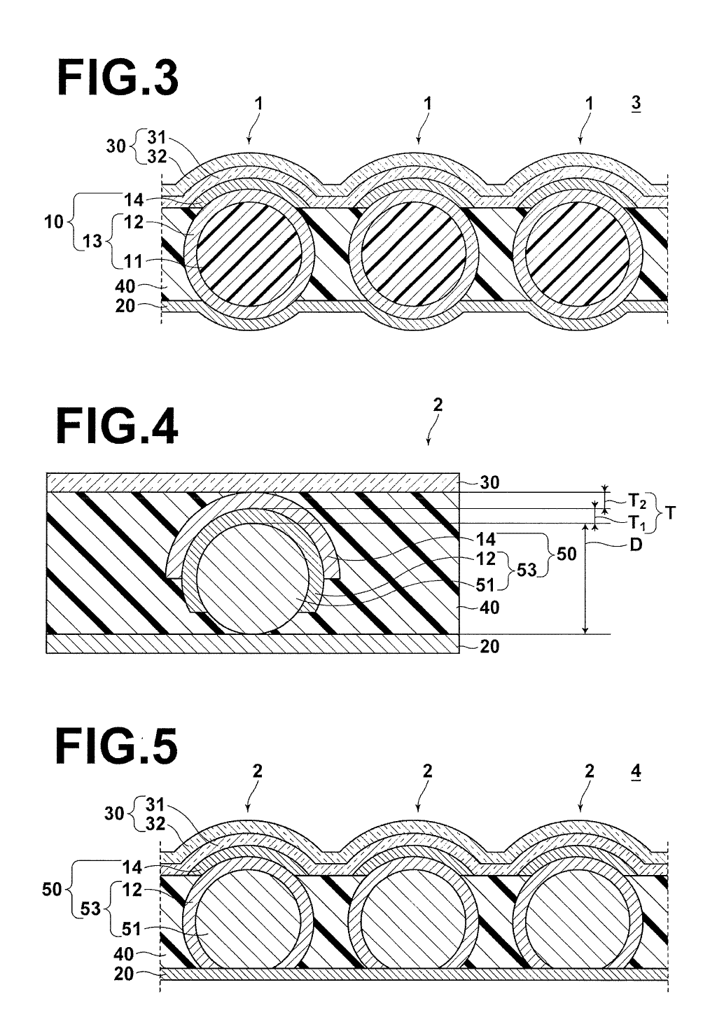

The method for producing the solar battery element 1 will be described with reference to FIG. 2 and FIG. 3. Here, a case in which a solar battery 3 having a great number of solar battery elements 1 arranged two dimensionally therein is produced will be described. A through F of FIG. 2 are sectional diagrams that illustrate production steps. FIG. 3 is a sectional diagram that illustrates a portion of the solar battery 3.

First, particles 13 (hereinafter, referred to as “first semiconductor particles 13”) are produced (not shown in FIG. 2) by forming the semiconductor layer of the first conductive type on the surfaces of the particulate base substance.

An example of a method for producing the first semiconductor particles 13 will be described. Here, a case will be described in which glass beads are employed as the particulate base substance, and CIS is employed as the semiconductor of the first conductive type.

CuIn alloy, S powder, and CuS flux are mixed, and the glass beads are introduced into this mixture. The mixture is sealed in a vacuum quartz ampule, and heated at a predetermined temperature for a predetermined amount of time (900° C. for 20 hours, for example) while the ampule is caused to move freely and rotate, to perform sintering. Thereafter, the CuS is removed by cleansing with a KCN aqueous solution, and the mixture is dried. Further, the mixture is sifted with a sieve having an appropriate sieve mesh size, to remove materials that are not adhered onto the glass beads. The first semiconductor particles 13 having glass beads 11 as their cores and CuInS semiconductor layers 12 of the first conductive type formed about their peripheries are produced by the method described above.

Note that it is desirable for the produced first semiconductor particles 13 to be sifted through a sieve or the like, such that the particle size distribution is within a range of approximately 30%.

Next, a pair of metal plates 101a and 101b are prepared, and a plurality of the first semiconductor particles 13 are placed on the metal plate 101b to form a single particle layer thereon, as illustrated in A of FIG. 2. It is desirable for the first semiconductor particles 13 to be placed to form a single particle layer by immobilizing the first semiconductor particles 13 with a weak adhesive layer provided on the metal plate 101b, or by forming regularly spaced recesses in the metal plate 101b. A Gel-Pak Sheet 102a (GEL-FILM™ WF-40/1.5-X4 by Gel-Pak, Inc.) that includes an elastic gel adhesive polymer layer and a polypropylene film of an appropriate thickness are held on the metal plate 101a in this order. Here, a case will be described in which the polypropylene film is employed as the insulating binder 40. However, any material may be used as long as it functions as the insulating binder 40.

Next, the polypropylene film 40 is arranged so as to cover a plurality of the first semiconductor particles 13, and pressure is applied from the upper surface of the metal plate 101a, as illustrated in B of FIG. 2. While the pressure is being applied, heat is applied at a temperature greater than or equal to the melting point of the polypropylene film. After the polypropylene film is sufficiently melted, the assembly is cooled. Here, the pressure which is applied is of a magnitude that enables the top portions of the plurality of first semiconductor particles 13 to sufficiently contact the Gel-Pak sheet 102a, without excessive force being applied thereto. For example, heating at 200° C. may be performed for several minutes in a state in which pressure of 180 g/cm² is being applied, then the assembly may be cooled naturally.

Next, the same processes are performed with the metal plate 101b as illustrated in C and D of FIG. 2. Thereafter, the metal plates 101a and 101b, the Gel-Pak sheets 102 and 102 are separated from the first semiconductor particles 13 and the polypropylene film 40, as illustrated in E of FIG. 2.

Thereby, a photoelectric converting layer, in which the plurality of first semiconductor particles 13 are arranged in a single particle layer such that portions thereof which are covered by the semiconductor layers of the first conductive type are exposed at a first surface 40a and a second surface 40b of the plate shaped insulating binder 40, is obtained as illustrated in F of FIG. 2.

Next, the first electrode 20 is formed on the first surface 40a of the insulating binder 40 (the surface of the photoelectric converting layer) such that it contacts the semiconductor layers 12 of the first conductive type.

Further, the semiconductor layers 14 of the second conductive type are formed on the semiconductor layers 12 of the first conductive type which are exposed at the second surface 40b of the insulating binder 40. Thereby, the photoelectric converting semiconductor particles 10, in which the first semiconductor particles 13 are covered by the semiconductor layers 14 of the second conductive type, are formed.

The semiconductor layers 14 of the second conductive type may be formed by the CBD (Chemical Bath Deposition) process or the like. For example, the top portions of the first semiconductor particles 13 that protrude from the insulating binder 40 may be immersed in an aqueous solution containing ammonia, cadmium sulfate, and thio urea, to form CdS layers on the surfaces thereof as the semiconductor layers 14 of the second conductive type. Note that CdS layers are so called buffer layers in CIS type thin film solar batteries. However, in the present specification, these buffer layers are also considered to be semiconductor layers of the second conductive type.

Next, the second electrode 30 is formed on the semiconductor layers 14 of the second conductive type. It is preferable for the second electrode 30 to be of a two layered structure having an i layer 31 having an i conductive type at the side of the semiconductor layer 14 of the second conductive type, and a layer 32 of the second conductive type. The second electrode 30 may be formed by a vapor phase film forming method, such as the electron beam vapor deposition method and the sputtering method.

The solar battery 3 provided with a plurality of the solar battery elements 1 as illustrated in FIG. 3 can be produced by the steps described above. The solar battery 3 is equipped with a so called single particle layer (monograin layer) as a photoelectric converting layer.

A glass cover, a protective film, or the like may be provided on the solar battery 3 as necessary, and the solar battery 3 may be employed as a solar battery module after being wired.

The solar battery element of the first embodiment and the method for producing the solar battery element of the first embodiment enable obtainment of the solar battery element 1 and the solar battery 3 equipped with a great number of solar battery elements 1, without complex steps that require highly precise positioning accuracy, such as the steps of grinding photoelectric converting semiconductor particles, forming apertures in an insulating member, and causing a conductive member to penetrate through the insulating member. Production costs can be reduced, particularly in the case that glass beads are employed as the particulate base substance of the photoelectric converting semiconductor particles 10 as in the present embodiment.

In the case that semiconductor particles are formed using a photoelectric converting semiconductor material to the cores thereof, light will not reach the core portions if the sizes of the semiconductor particles become large. Therefore, the core portions contribute very little to light absorption (photoelectric conversion), and the photoelectric converting semiconductor material cannot sufficiently exhibit the function thereof, which is wasteful. The present invention employs a particulate base substance, which is a less expensive material than semiconductor materials, as the core portions that contribute very little to light absorption. Therefore, an advantageous effect that cost can be suppressed is obtained. In addition, in the case that semiconductor particles formed to the cores thereof by a photoelectric converting semiconductor material are of sizes that enable the core portions thereof to contribute to light absorption, the particle sizes thereof become small and there is a possibility that the handling properties thereof will deteriorate. In contrast, the present invention employs semiconductor particles having the particulate base substance in their interiors. Therefore, the particle sizes thereof can be increased, and handling properties are improved.

### <Second Embodiment of Solar Battery Element>

FIG. 4 is a sectional diagram that schematically illustrates the construction of a solar battery element 2 according to a second embodiment of the present invention. Note that elements which are the same as the constituent element of the solar battery element 1 of the first embodiment will be denoted by the same reference numerals, and detailed descriptions thereof will be omitted.

As illustrated in FIG. 4, the solar battery element 2 of the present embodiment is equipped with: a photoelectric converting semiconductor particle 50 formed by a conductive particulate base substance 51, a semiconductor layer 12 of a first conductive type that cover the particulate base substance 51 such that at least a portion thereof is exposed, and a semiconductor layer 14 of a second conductive type that covers at least a portion of the semiconductor layer 12 of the first conductive type; a first electrode 20 that contacts the particulate base substance 51; a second electrode 30 that contacts the semiconductor layer 14 of the second conductive type; and an insulating binder 40 for immobilizing the photoelectric converting semiconductor particle 50 between the first electrode 20 and the second electrode 30.

The first electrode 20, the second electrode 30, and the insulating binder 40 are the same as those of the solar battery element 1 of the previously described first embodiment.

### (Photoelectric Converting Semiconductor Particle)

As described above, the photoelectric converting semiconductor particle 50 of the present embodiment is constituted by: the conductive particulate base substance 51, the semiconductor layer 12 of the first conductive type that cover the particulate base substance 51 such that at least a portion thereof is exposed, and the semiconductor layer 14 of the second conductive type that covers at least a portion of the semiconductor layer 12 of the first conductive type. The semiconductor layer 12 of the first conductive type covers the particulate base substance 51 such that at least a portion thereof is exposed so as to enable the particulate base substance 51 can contact the first electrode 20, as illustrated in FIG. 4. In addition, in the present embodiment, the semiconductor layer 14 of the second conductive type is provided only at the upper portion of the first semiconductor particle 13 constituted by the particulate base substance 51 and the semiconductor layer 12 of the first conductive type that covers a portion of the particulate base substance 51. That is, a configuration is adopted in which the semiconductor layer 12 is prevented from contacting the second electrode 30.

The preferred shape of the conductive particulate base substance 51, the preferred particle size of the conductive particulate base substance 51, the preferred thicknesses of the semiconductor layers 12 and 14 of the first and second conductive types are the same as those of the particulate base substance 11, etc. of the first embodiment. In addition, the materials of the semiconductor layer 12 of the first conductive type and the semiconductor layer 14 of the second conductive type are the same as those of the solar battery element 1 of the first embodiment.

The material of the conductive particulate substance 51 is not particularly limited as long as it is a conductive material. It is preferable for the conductive particulate substance 51 to be formed by the same material as that of the first electrode 20.

The conductive particulate substance 51 contacts the first electrode 20, and functions as a part of the underside electrode. Because the contact area with the semiconductor layer 12 of the first conductive type is great, electric charges can be drawn out efficiently.

### <Method for Producing the Solar Battery Element of the Second Embodiment>

The method for producing the solar battery element 2 includes substantially the same steps as the method for producing the solar battery element 1. A method for producing a solar battery 4, in which a great number of the solar battery elements 2 are arranged two dimensionally, will be described mainly with respect to points that differ from the method for producing the solar battery 3. FIG. 5 is a sectional diagram that illustrates a portion of the solar battery 4.

First, first semiconductor particles 53 are produced by forming the semiconductor layer of the first conductive type on the surfaces of the conductive particulate base substance 51. An example of a method for producing the first semiconductor particles 53 will be described. Here, a case will be described in which Mo particles are employed as the particulate base substance 51, and CIS is employed as the semiconductor of the first conductive type.

CuIn alloy, S powder, and CuS flux are mixed, and the Mo particles, which are to become core portions, are introduced into this mixture. The mixture is sealed in a vacuum quartz ampule, and heated at a predetermined temperature for a predetermined amount of time (900° C. for 20 hours, for example) while the ampule is caused to move freely and rotate, to perform sintering. Thereafter, the CuS is removed by cleansing with a KCN aqueous solution, and the mixture is dried. Further, the mixture is sifted with a sieve having an appropriate sieve mesh size, to remove materials that are not adhered onto the Mo particles. The first semiconductor particles 53 having Mo particles 51 as their cores and CuInS semiconductor layers 12 of the first conductive type formed about their peripheries are produced by the method described above.

Note that it is desirable for the produced first semiconductor particles 53 to be sifted through a sieve or the like, such that the particle size distribution is within a range of approximately 30%.

The steps for arranging the first semiconductor particles 53 such that portions thereof which are covered by the semiconductor layers of the first conductive type are exposed at a first surface 40a and a second surface 40b of the plate shaped insulating binder 40 are the same as those of the first embodiment.

The semiconductor layers 12 of the first conductive type on the first semiconductor particles 53 that protrude from a first surface of a photoelectric converting layer (the first surface 40a of the plate shaped insulating binder), which is a single particle layer, are ground to expose the conductive particulate base substance 51.

Thereafter, the first electrode 20 is formed on the first surface 40a of the insulating binder 40 (the surface of the photoelectric converting layer) such that it contacts the exposed conductive base substance 51.

Further, the semiconductor layers 14 of the second conductive type are formed on the semiconductor layers 12 of the first conductive type which are exposed at the second surface 40b of the insulating binder 40. Thereby, the photoelectric converting semiconductor particles 50, in which the first semiconductor particles 53 are covered by the semiconductor layers 14 of the second conductive type, are formed.

Next, the second electrode 30 is formed on the semiconductor layers 14 of the second conductive type. The semiconductor layers 14 of the second conductive type and the second electrode 30 may be formed in the same manner as in the case of the first embodiment.

The solar battery 4 provided with a plurality of the solar battery elements 2 as illustrated in FIG. 5 can be produced by the steps described above.

The solar battery element of the second embodiment and the method for producing the solar battery element of the second embodiment enable obtainment of the solar battery element 2 and the solar battery 5 equipped with a great number of the solar battery elements 2, without complex steps that require highly precise positioning accuracy, such as the steps of forming apertures in an insulating member, and causing a conductive member to penetrate through the insulating member.

### EMBODIMENTS

The solar battery 3 illustrated in FIG. 3 was produced as Embodiment 1, the solar battery 4 illustrated in FIG. 5 was produced as Embodiment 2, and the photoelectric conversion rates thereof were measured. In addition, a solar battery was produced according to the method disclosed in U.S. Patent Application Publication No. 20070089782 as a comparative example, and the photoelectric conversion rate thereof was measured. The details will be described hereinbelow.

### Embodiment 1

A CuIn (5/5) alloy and S powder were mixed at a ratio of 1:2 (molar ratio). Further, CuS flux was added such that the amount thereof was 40% by volume of the total mixture, and mixed as well. Glass beads (insulating base substance) 11 having an average diameter of 55 μm were introduced into this mixture such that the ratio with respect to the CuIn alloy was 5:1 (glass beads:CuIn alloy). The mixture was sealed in a vacuum quartz ampule, and heated at 900° C. for 20 hours while the ampule is caused to move freely and rotate, to perform sintering. Thereafter, the CuS was removed by cleansing with a 10% KCN aqueous solution, and the mixture was dried. Then, the mixture was sifted with a sieve having a sieve mesh size of 50 μm, to remove materials that were not adhered onto the glass beads. First semiconductor particles 13 obtained in this manner had the glass beads 11 as their cores and 2 μm thick CuInS semiconductor layers 12 formed on the entireties of the surfaces thereof.

Next, a pair of metal plates 101a and 101b (80 μm thick aluminum foil) were prepared. Regularly spaced recesses were provided in the metal plate 101b, a plurality of the first semiconductor particles 13 were scattered onto the metal plate 101b, which was then vibrated, to form a single particle layer.

An elastic Gel-Pak Sheet 102a (GEL-FILM™ WF-40/1.5-X4 by Gel-Pak, Inc.) and a polypropylene film 40 (TRANSPROP™ 0L propylene film by Translilwrap Company, Inc.) were held on the metal plate 101a in this order. The polypropylene film 40 was arranged so as to cover a plurality of the first semiconductor particles 13, and pressure of 180 g/cm² was applied from the back surfaces of the metal plates 101a and 101b. Heating at 200° C. was performed for 5 minutes while the pressure was being applied. Thereafter, heat was naturally dissipated to cool the assembly.

The same processes were performed with respect to the other sides of the first semiconductor particles 13. Thereafter, the metal plates 101a and 101b, the Gel-Pak sheets 102 and 102 were separated from the first semiconductor particles 13 and the polypropylene film 40. Thereby, a single particle semiconductor layer (photoelectric converting layer), in which the plurality of first semiconductor particles 13 are arranged such that the top portions and the bottom portions thereof are exposed at the surfaces of the polypropylene film 40, was obtained.

A 0.8 μm thick metal film formed by Mo was formed as a first electrode 20 on a first surface 40a of the photoelectric converting layer (the surface at which the bottom portions of the first semiconductor particles are exposed) by the sputtering method. In addition, the opposite surface 40b (the surface at which the top portions of the first semiconductor particles are exposed) was immersed in an aqueous solution containing ammonia, cadmium sulfate, and thio urea, to form CdS layers as semiconductor layers 14 of the second conductive type (here, the n type) on the top portions of the first semiconductor particles.

Photoelectric converting semiconductor particles having glass beads as spherical cores, semiconductor layers of the first conductive type covering the entireties of the surfaces of the spherical cores, and semiconductor layers of the second conductive type covering portions of the semiconductor layers of the first type were obtained in the manner described above.

Further, an 80 nm thick i-ZnO layer and a 500 nm thick ZnO:Al layer were sequentially formed on the CdS layers as a transparent second electrode by the sputtering method, to obtain the solar battery 3 illustrated in FIG. 3.

Light having an intensity of 100 mW/m² was irradiated onto the obtained solar battery by a solar simulator equipped with a xenon light source and an AM (Air Mass) 1.5 filter. The photoelectric converting efficiency of the solar battery was measured by measuring the current-voltage properties thereof. The photoelectric converting efficiency was 8%.

### Embodiment 2

A CuIn (5/5) alloy and S powder were mixed at a ratio of 1:2 (molar ratio). Further, CuS flux was added such that the amount thereof was 40% by volume of the total mixture, and mixed as well. Spherical Mo particles (conductive base substance) 51 having an average diameter of 55 μm were introduced into this mixture such that the ratio with respect to the CuIn alloy was 5:1 (glass beads:CuIn alloy). The mixture was sealed in a vacuum quartz ampule, and heated at 900° C. for 20 hours while the ampule is caused to move freely and rotate, to perform sintering. Thereafter, the CuS was removed by cleansing with a 10% KCN aqueous solution, and the mixture was dried. Then, the mixture was sifted with a sieve having a sieve mesh size of 50 μm, to remove materials that were not adhered onto the glass beads. First semiconductor particles 53 obtained in this manner had the Mo particles 51 as their cores and 2 μm thick CuInS semiconductor layers 12 formed on the entireties of the surfaces thereof.

A single particle semiconductor layer (photoelectric converting layer), in which the plurality of first semiconductor particles 53 are arranged such that the top portions and the bottom portions thereof are exposed at the surfaces of a polypropylene film, was obtained by the same method as in Embodiment 1.

The bottom portions of the first semiconductor particles 53 were ground to scrape away the CuInS layers 12 and to expose the Mo particles 51 in the interiors thereof at a first surface 40a of the photoelectric converting layer (the surface at which the bottom portions of the first semiconductor particles are exposed). Thereafter, a 0.8 μm thick metal film formed by Mo was formed as a first electrode 20 on this surface by the sputtering method.

In addition, the opposite surface 40b (the surface at which the top portions of the first semiconductor particles are exposed) was immersed in an aqueous solution containing ammonia, cadmium sulfate, and thio urea, to form CdS layers as semiconductor layers 14 of the second conductive type on the top portions of the first semiconductor particles 53.

Photoelectric converting semiconductor particles having Mo particles 51 as spherical cores, semiconductor layers 12 of the first conductive type covering at least portions of the surfaces of the spherical cores, and semiconductor layers 14 of the second conductive type covering portions of the semiconductor layers 12 of the first type were obtained in the manner described above.

Further, an 80 nm thick i-ZnO layer 31 and a 500 nm thick ZnO:Al layer 32 were sequentially formed on the CdS layers as a transparent second electrode by the sputtering method, to obtain the solar battery 4 illustrated in FIG. 5.

The photoelectric converting efficiency of the obtained solar battery was measured in the same manner as that for Embodiment 1. The measured photoelectric converting efficiency was 8%.

### Comparative Example 1

Mo films were formed on an insulating base substrate (glass beads) having an average diameter of 50 μm by sputtering. Cu—In alloy films were formed on the Mo films and then sulfidized to form 2 μm thick p type CuInS semiconductor layers. The glass beads having the Mo films and the CuInS semiconductor layers thereon were designated as first semiconductor particles. The first semiconductor particles were immersed in an aqueous solution containing ammonia, cadmium sulfate, and thio urea, to form CdS layers (buffer layers) on the surfaces thereof as second semiconductor layers.

Thereafter, a single particle semiconductor layer (photoelectric converting layer), in which a plurality of photoelectric converting semiconductor particles are arranged such that the top portions and the bottom portions thereof are exposed at the surfaces of a polypropylene film, was obtained by the same method as in Embodiment 1. Then, the bottom portions of the photoelectric converting semiconductor particles were ground until the Mo films within their interiors are exposed, and a metal film formed by Mo was provided as a first electrode in the same manner as in Embodiment 1. Further, an 80 nm thick i-ZnO layer and a 500 nm thick ZnO:Al layer were sequentially formed on the top portions of the photoelectric converting particles as a transparent second electrode by the sputtering method.

The photoelectric converting efficiency of the solar battery obtained by the method described above was measured in the same manner as that for Embodiment 1. The measured photoelectric converting efficiency was 4%.

It is estimated that the reason why the converting efficiency of the solar battery of Comparative Example 1 was low is because not only the Mo films and the semiconductor layers of the first conductive type, but also the edge portions of the semiconductor layers of the second conductive type were in contact with the first electrode. In contrast, the semiconductor layers of the second conductive type do not contact the first electrodes in the solar batteries of Embodiments 1 and 2. Therefore, high converting efficiencies compared to that of Comparative Example 1 were obtained.

What is claimed is:

1. A solar battery element, comprising:
photoelectric converting semiconductor particles formed by a particulate base substance, semiconductor layers of a first conductive type formed by a material different from that of the particulate base substance that cover at least portions of the particulate base substance, and semiconductor layers of a second conductive type that cover portions of the semiconductor layers of the first conductive type so as to form pn junctions therewith;
a first electrode that contacts the semiconductor layers of the first conductive type;
a second electrode that contacts the semiconductor layers of the second conductive type; and
an insulating binder for immobilizing the photoelectric converting semiconductor particles between the first electrode and the second electrode.

2. A solar battery element as defined in claim 1, wherein:
the semiconductor layers of the first conductive type cover the entire surface of the particulate base substance in the photoelectric converting semiconductor particles.

3. A solar battery element as defined in claim 1, wherein:
the particle size of the particulate base substance is within a range from 5 μm to 1000 μm; and
the ratio of the particle size of the particulate base substance with respect to an average total thickness of the semiconductor layers of the first conductive type and the semiconductor layers of the second conductive type is within a range from 2 to 1000.

4. A solar battery element as defined in claim 1, wherein:
the semiconductor layers of the first conductive type are one of p type group IB-IIIB-VIB semiconductors and p type group IB-IIB-IVB-VIB semiconductors.

5. A solar battery element as defined in claim 1, wherein:
the semiconductor layers of the second conductive type are one of n type IIB-VIB group semiconductors, n type IB-IIB-IIIB-VIB group semiconductors, and n type IB-IIIB-IVB-VIB group semiconductors.

6. A solar battery element, comprising:
photoelectric converting semiconductor particles formed by a conductive particulate base substance, semiconductor layers of a first conductive type that cover the particulate base substance such that at least portions thereof are exposed, and semiconductor layers of a second conductive type that cover at least portions of the semiconductor layers of the first conductive type so as to form pn junctions therewith;
a first electrode that contacts the particulate base substance;
a second electrode that contacts the semiconductor layers of the second conductive type; and
an insulating binder for immobilizing the photoelectric converting semiconductor particles between the first electrode and the second electrode.

7. A solar battery element as defined in claim 6, wherein:
the particle size of the conductive particulate base substance is within a range from 5 μm to 1000 μm; and
the ratio of the particle size of the particulate base substance with respect to an average total thickness of the semiconductor layers of the first conductive type and the semiconductor layers of the second conductive type is within a range from 2 to 1000.

8. A solar battery element as defined in claim 6, wherein:
the semiconductor layers of the first conductive type are one of p type group IB-IIIB-VIB semiconductors and p type group IB-IIB-IVB-VIB semiconductors.

9. A solar battery element as defined in claim 6, wherein:
the semiconductor layers of the second conductive type are one of n type IIB-VIB group semiconductors, n type IB-IIB-IIIB-VIB group semiconductors, and n type IB-IIIB-IVB-VIB group semiconductors.

10. A method for producing the solar battery element of claim 1, comprising the steps of:
producing first semiconductor particles, by coating a particulate base substance with semiconductor layers of a first conductive type formed by a material different from that of the particulate base substance such that at least portions of the particulate base substance are covered;
arranging the first semiconductor particles in a plate shaped insulating binder such that the portions covered by the semiconductor layers of the first conductive type are exposed at both a first surface and a second surface of the insulating binder;
forming a first electrode on the first surface of the insulating binder so as to contact the semiconductor layers of the first conductive type;
forming semiconductor layers of a second conductive type on the semiconductor layers of the first conductive type, which are exposed at the second surface of the insulating binder; and
forming a second electrode on the semiconductor layers of the second conductive type.

11. A method for producing the solar battery element of claim 6, comprising the steps of:
producing first semiconductor particles, by coating a conductive particulate base substance with semiconductor layers of a first conductive type;
arranging the first semiconductor particles in a plate shaped insulating binder such that the portions covered by the semiconductor layers of the first conductive type are exposed at both a first surface and a second surface of the insulating binder;
grinding the semiconductor layers of the first conductive type which are exposed at the first surface of the insulating binder to expose the conductive particulate base substance;
forming a first electrode so as to contact the exposed conductive particulate base substance;
forming semiconductor layers of a second conductive type on the semiconductor layers of the first conductive type, which are exposed at the second surface of the insulating binder; and
forming a second electrode on the semiconductor layers of the second conductive type.
